(19) United States
(12) Patent Application Publication
(10) Pub. No.: US 2026/0091571 A1
(43) Pub. Date: Apr. 2, 2026

(54) LAMINATED FILM AND METHOD FOR PRODUCING LAMINATED FILM

(71) Applicant: Murata Manufacturing Co., Ltd., Nagaokakyo-shi (JP)

(72) Inventor: Hiroyuki MASAKI, Nagaokakyo-shi (JP)

(21) Appl. No.: 19/411,554

(22) Filed: Dec. 8, 2025

Related U.S. Application Data
(63) Continuation of application No. PCT/JP2024/005011, filed on Feb. 14, 2024.

(30) Foreign Application Priority Data
Jun. 13, 2023 (JP) 2023-096987

(51) Int. Cl. B32B 15/08; B32B 27/08; B32B 37/10; B32B 37/12; B32B 38/00

(52) U.S. Cl. CPC B32B 15/08; B32B 27/08; B32B 37/10; B32B 37/12; B32B 38/0008; B32B 2250/04; B32B 2262/02; B32B 2305/026; B32B 2305/55; B32B 2310/0875; B32B 2310/14

(57) ABSTRACT

A laminated film that includes: a porous resin layer having a first molded body of first liquid crystal polymer fibers; a first adhesive layer on the porous resin layer; a metal layer on the first adhesive layer on a side thereof opposite to the porous resin layer as viewed from the first adhesive layer; and a second adhesive layer on the porous resin layer on a side thereof opposite to the first adhesive layer as viewed from the porous resin layer.

### CROSS REFERENCE TO RELATED APPLICATIONS

The present application is a continuation of International application No. PCT/JP2024/005011, filed Feb. 14, 2024, which claims priority to Japanese Patent Application No. 2023-096987, filed Jun. 13, 2023, the entire contents of each of which are incorporated herein by reference.

### TECHNICAL FIELD

The present disclosure relates to a laminated film and a method for producing the laminated film.

### BACKGROUND ART

Patent Document 1 (Japanese Patent Application Laid-Open No. 2020-53632) discloses a low dielectric substrate material including a porous resin layer, an adhesive layer, and a metal layer in order in a thickness direction, in which a thickness d1 of the adhesive layer and a thickness d2 of the porous resin layer satisfy the following formula (1).

d1/d2≤0.5 (1)

Patent Document 2 (Japanese Patent Application Laid-Open No. 2004-82372) discloses an insulating material for a high-frequency wiring substrate in which an adhesive layer is formed on at least one surface of a resin porous layer, and a difference between a dielectric constant of the resin porous layer at 10 GHz and a dielectric constant of the adhesive layer at 10 GHz is 0.4 or less.
Patent Document 1: Japanese Patent Application Laid-Open No. 2020-53632
Patent Document 2: Japanese Patent Application Laid-Open No. 2004-82372

### SUMMARY OF THE DISCLOSURE

As described in Patent Documents 1 and 2, a substrate material including a porous resin layer and an adhesive layer has been studied as a laminated film for a substrate material. However, the laminated film including the adhesive layer has a relatively large dielectric loss.

The present disclosure has been made in view of the above problem, and an object of the present disclosure is to provide a laminated film including a porous resin layer and an adhesive layer and having a small dielectric loss.

A laminated film according to the present disclosure includes: a porous resin layer having a first molded body of first liquid crystal polymer fibers; a first adhesive layer on the porous resin layer; a metal layer on the first adhesive layer on a side thereof opposite to the porous resin layer as viewed from the first adhesive layer; and a second adhesive layer on the porous resin layer on a side thereof opposite to the first adhesive layer as viewed from the porous resin layer.

In the laminated film according to the present disclosure, the porous resin layer is a molded body of liquid crystal polymer fibers, thereby reducing the dielectric loss tangent of the laminated film. Therefore, it is possible to provide a laminated film including a porous resin layer and an adhesive layer and having a small dielectric loss.

### BRIEF EXPLANATION OF THE DRAWINGS

FIG. 1 is a sectional view illustrating a laminated film according to an embodiment of the present disclosure.

FIG. 2 is a flowchart illustrating a method for producing a laminated film according to an embodiment of the present disclosure.

FIG. 3 is a sectional observation photograph by SEM of the double-sided copper-clad laminate according to Example 1.

FIG. 4 is a sectional observation photograph by SEM of the double-sided copper-clad laminate according to Example 4.

FIG. 5 is a sectional observation photograph by SEM of the double-sided copper-clad laminate according to Reference Example.

### DESCRIPTION OF THE PREFERRED EMBODIMENTS

Hereinafter, the laminated film of an embodiment of the present disclosure will be described, but the present disclosure is not limited thereto. In addition, in the following description of the embodiments, the same or corresponding parts in the drawings will be denoted by the same reference numerals and the description thereof will not be repeated.

### Laminated Film

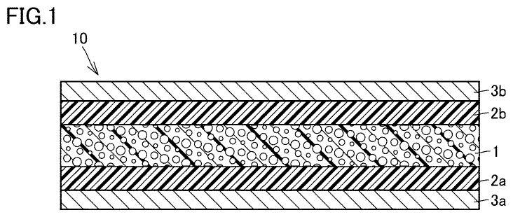

FIG. 1 is a sectional view illustrating a laminated film according to an embodiment of the present disclosure. As illustrated in FIG. 1, a laminated film 10 according to an embodiment of the present disclosure includes a porous resin layer 1, a first adhesive layer 2a, a second adhesive layer 2b, a first metal layer 3a, and a second metal layer 3b. The first adhesive layer 2a is laminated on the porous resin layer 1. The first metal layer 3a is laminated on the first adhesive layer 2a on the opposite side of the porous resin layer 1 as viewed from the first adhesive layer 2a. The second adhesive layer 2b is laminated on the porous resin layer 1 on the opposite side of the first adhesive layer 2a as viewed from the porous resin layer 1. The second metal layer 3b is laminated on the second adhesive layer 2b on the opposite side of the porous resin layer 1 as viewed from the second adhesive layer 2b. The laminated film 10 may not include the second adhesive layer 2b.

The dielectric loss tangent of the laminated film according to an embodiment of the present disclosure is relatively small. The dielectric loss tangent of the laminated film according to the present embodiment measured by applying a high-frequency signal of 12 GHz at an ambient temperature of 25° C. by a cavity resonator method using a dielectric constant measurement device in accordance with JIS R 1641 is, for example, 0.005 or less, preferably 0.03 or less.

Then, each of the porous resin layer 1, the first adhesive layer 2a, the second adhesive layer 2b, the first metal layer 3a, and the second metal layer 3b will be described. The same type of adhesive layer can be adopted as the first adhesive layer 2a and the second adhesive layer 2b. The first adhesive layer 2a and the second adhesive layer 2b may be adhesive layers of the same type or may be adhesive layers different from each other. Also for the first metal layer 3a and the second metal layer 3b, the same type of metal layer can be adopted. The first metal layer 3a and the second metal layer 3b may be metal layers of the same type as each other, or may be metal layers different from each other.

### Porous Resin Layer

The porous resin layer in the present embodiment has a porosity of, for example, 25% to 50%. When the porosity is 25% or more, the porous resin layer can have a desired function as a porous body, and for example, having air in the voids allows the dielectric constant to be relatively low. In addition, when the porosity is 50% or less, it is possible to suppress the strength of the laminated film from becoming too low. The porosity is calculated based on the weight of the porous resin layer, the thickness of the porous resin layer, and the density of the raw material resin of the porous resin layer. The thickness of the porous resin layer may be measured using, for example, a scanning electron microscope (SEM). In addition, the porous resin layer in the present embodiment has an average pore size of, for example, 1 μm or less as measured by a mercury intrusion method.

The porous resin layer in the present embodiment is a molded body of liquid crystal polymer fibers (LCP fiber molded body). The porous resin layer is an LCP fiber molded body, and thus the dielectric loss tangent of the laminated film is reduced, and consequently the dielectric loss of the laminated film can be reduced. The LCP fiber molded body has a plate shape, and is molded with liquid crystal polymer powder (LCP powder). This LCP powder includes fibrous particles including liquid crystal polymer (liquid crystal polymer fiber: LCP fiber).

At least one surface of the LCP fiber molded body is preferably subjected to plasma treatment. At least one surface of the LCP fiber molded body is subjected to plasma treatment by being irradiated with plasma, thereby improving adhesion between the LCP fiber molded body and the first adhesive layer and/or the second adhesive layer. The LCP fiber molded body may not be subjected to plasma treatment. It is most preferable that both surfaces of the LCP fiber molded body are subjected to plasma treatment.

### Liquid Crystal Polymer Powder

The liquid crystal polymer is not particularly limited, and examples thereof include a thermotropic liquid crystal polymer. The thermotropic liquid crystal polymer is, for example, an aromatic polyester synthesized mainly containing a monomer such as an aromatic diol, an aromatic dicarboxylic acid, or an aromatic hydroxycarboxylic acid, and exhibits liquid crystallinity during melting.

A molecule of the liquid crystal polymer has a negative linear expansion coefficient (CTE) in an axial direction of a molecular axis and a positive CTE in a radial direction of the molecular axis.

The liquid crystal polymer preferably has no amide bond. Examples of the thermotropic liquid crystal polymer having no amide bond include a copolymer of parahydroxybenzoic acid, terephthalic acid, and dihydroxybiphenyl (a copolymer of parahydroxybenzoic acid and ethylene terephthalate) having a high melting point (melting point of approximately 350° C.) and a low CTE, which is called a type-1 liquid crystal polymer, and a copolymer of parahydroxybenzoic acid and 2,6-hydroxynaphthoic acid having a melting point (melting point of approximately 320° C.) between a type-1 liquid crystal polymer and a type-2 liquid crystal polymer, which is called type-1.5 (or type-3).

The LCP fibers included in the LCP powder are not particularly limited as long as they include a fibrous portion. The fibrous portion may be linear or may have branching or the like.

An average diameter of the LCP fibers is 2 μm or less and preferably 1 μm or less. In addition, the average aspect ratio of the LCP fibers is preferably 10 to 500, and more preferably 10 to 300.

The average diameter and average aspect ratio of the LCP fibers are measured by the following method.

The LCP powder composed of the LCP fibers to be measured is dispersed in acetone to prepare a slurry in which 0.01 mass % of the LCP powder is dispersed. In this case, the slurry was prepared such that a moisture content in the slurry was 1 mass % or less. Then, 5 μL to 10 μL of this slurry is dropped onto a silicon substrate, and then the slurry on the silicon substrate is naturally dried. The LCP powder is disposed on the silicon substrate by naturally drying the slurry.

Then, a predetermined region of the LCP powder disposed on the silicon substrate is observed with a scanning electron microscope (SEM) to collect 100 or more pieces of image data of the particles (the LCP fibers) constituting the LCP powder. In the collection of the image data, the region is set according to the size per particle of the LCP such that the number of image data was 100 or more. In addition, for each particle of the LCP, the image data is collected by appropriately changing a magnification of the SEM to 500 times, 3,000 times, or 10,000 times in order to suppress leakage of the collection of the image data and occurrence of a measurement error.

Then, a longitudinal direction dimension and a width direction dimension of each of the LCP fibers are measured using the collected image data.

In one of the LCP fibers photographed in each piece of the image data, a direction of a straight line connecting both ends of a longest path in a path from one end portion to an end portion opposite to the one end portion through substantially a center of the particle is defined as a longitudinal direction. Then, a length of a straight line connecting both ends of the longest path is measured as the longitudinal direction dimension.

In addition, a particle dimension of one particle of the LCP powder in a direction orthogonal to the longitudinal direction is measured at three different points in the longitudinal direction. An average value of the dimensions measured at these three points was taken as the width direction dimension (fiber size) per particle of the LCP powder.

Further, a ratio of the longitudinal direction dimension to the fiber size [longitudinal dimension/fiber size] is calculated and taken as the aspect ratio of the LCP fibers.

Then, the average value of the fiber sizes measured for 100 LCP fibers is taken as the average diameter.

In addition, the average value of the aspect ratios measured for 100 LCP fibers is taken as the average aspect ratio.

The fibrous particles may be included in the LCP powder as an aggregate in which the fibrous particles are aggregated.

In addition, in the fibrous particles, the axial direction of the LCP molecules constituting the fibrous particles and the longitudinal direction of the fibrous particles tend to coincide with each other. It is considered that this is because, in a case where the LCP powder is produced, the axial direction of the LCP molecules is oriented along the longitudinal direction of the fibrous particles due to breakage between a plurality of domains formed by bundling the LCP molecules.

In the LCP powder, a content (a number ratio) of particles other than the fibrous particles (massive particles that are not substantially fibrous) is preferably 20% or less. For example, when the LCP powder is placed on a plane, particles having a maximum height of 10 μm or less are fibrous particles, and particles having a maximum height of more than 10 μm are massive particles.

The LCP powder preferably has a D50 (an average particle size) value of 13 μm or less as measured by particle size measurement using a particle size distribution measuring device by a laser diffraction scattering method.

### Adhesive Layer (First Adhesive Layer 2a, Second Adhesive Layer 2b)

The material of the adhesive layer is not particularly limited, but is preferably a layer including a low dielectric constant resin. As the adhesive layer, for example, an applied product of an adhesive including a low dielectric constant resin, a sheet including a low dielectric constant resin, or the like can be used. Examples of these resins include polyimide-based resins such as modified polyimide-based resins, fluororesins, polyphenylene oxide, polyphenylene ether, bismaleimide triazine, epoxy resins, phenol resins, and modified products thereof. Among these, an epoxy-based resin sheet is preferably used.

In addition, it is preferable that the adhesive layer includes a liquid crystal polymer. The adhesive layer includes the liquid crystal polymer, thereby allowing the dielectric loss of the laminated film to be further reduced. As the liquid crystal polymer included in the adhesive layer, those used as the liquid crystal polymer of the liquid crystal polymer powder described above can be employed.

However, in the production of the laminated film described later, from the viewpoint of suppressing melting of the adhesive layer, the melting point of the liquid crystal polymer included in the adhesive layer is preferably different from the melting point of the liquid crystal polymer included in the porous resin layer. More specifically, the melting point of the liquid crystal polymer included in the porous resin layer is preferably higher than the melting point of the liquid crystal polymer included in the adhesive layer. This makes it easy to heat the adhesive layer including the liquid crystal polymer to adhere the adhesive layer to other layers such as the porous resin layer and the metal layer while maintaining the function as the porous resin layer in the LCP fiber molded body. Further, the melting point of the liquid crystal polymer included in the porous resin layer is more preferably 20° C. higher than the melting point of the liquid crystal polymer included in the adhesive layer. This makes it easier to heat the adhesive layer including the liquid crystal polymer to adhere the adhesive layer to other layers such as the porous resin layer and the metal layer while maintaining the function as the porous resin layer in the LCP fiber molded body.

As the adhesive layer including a liquid crystal polymer, a liquid crystal polymer film obtained by molding a liquid crystal polymer into a film shape, an LCP fiber molded body, or the like can be used. As the adhesive layer including a liquid crystal polymer, an LCP fiber molded body is preferably used. This further improves adhesion between the adhesive layer and the porous resin layer. As the LCP fiber molded body constituting the adhesive layer, an LCP fiber molded body capable of being employed as a porous resin layer can be used. In addition, similarly to the LCP fiber molded body capable of being employed as the porous resin, the LCP fiber molded body constituting the adhesive layer is preferably subjected to plasma treatment from the viewpoint of improving adhesion with other layers.

The thickness of the adhesive layer is, for example, 2 μm or more, preferably 5 μm or more. In addition, the thickness of the adhesive layer is, for example, 50 μm or less, preferably 25 μm or less.

### Metal Layer (First Metal Layer 3a, Second Metal Layer 3b)

Specifically, the metal layer includes a metal foil. The metal layer (metal foil) is preferably copper, copper alloy, one plated on a copper surface, or the like from the viewpoint of conductivity, processability, and the like as a wiring pattern. The thickness of the metal layer (metal foil) is preferably 1 μm to 50 μm. The surface of the metal foil may be subjected to various physical or chemical surface treatments such as a roughening treatment and a black treatment in order to enhance adhesion to the adhesive layer.

As a method for bonding the metal layer (metal foil) to the adhesive layer, in a state where the metal foil is laminated on the adhesive layer, bonding by hot pressing, bonding by heating, or the like may be performed. Various press apparatuses such as a vacuum press apparatus, a hot press apparatus, and a continuous press apparatus can be used for the hot press, and as the temperature and pressure of the hot press, any conventionally known conditions that cause a curing reaction of the adhesive can be applied. In the present embodiment, a vacuum press is employed as described later.

### Method for Producing Laminated Film

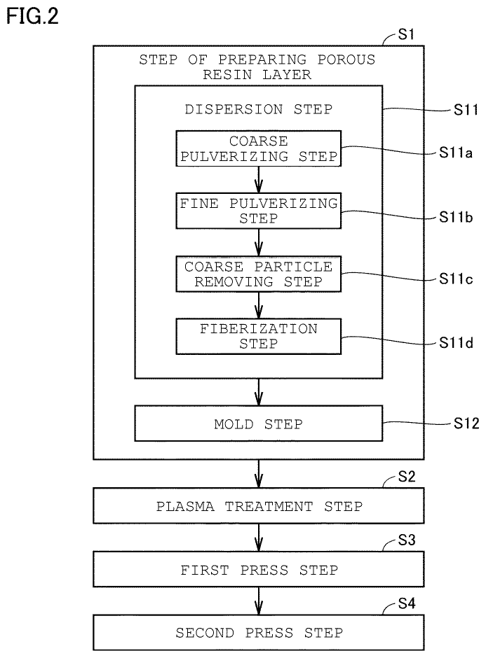

Hereinafter, a method of producing a laminated film according to an embodiment of the present disclosure will be described. FIG. 2 is a flowchart illustrating a method for producing a laminated film according to an embodiment of the present disclosure. As shown in FIG. 2, the method for producing a laminated film according to an embodiment of the present disclosure includes a step S1 of preparing a porous resin layer, a plasma treatment step S2, a first press step S3, and a second press step S4.

### Step S1 of Preparing Porous Resin Layer

The step S1 of preparing the porous resin layer includes dispersion step S11 and molding step S12.

### Dispersion Step S11

First, the dispersion step S11 according to the present embodiment will be described below, and in the dispersion step S11, a liquid crystal polymer powder in a slurry state is obtained. However, the method for obtaining the liquid crystal polymer powder in a slurry state is not limited to the following dispersion step S11.

In the dispersion step S11 according to the present embodiment, the LCP powder to be a raw material of the molded body of the liquid crystal polymer fibers as the porous resin layer is dispersed in the dispersion medium to form a paste or slurry. In the present embodiment, the LCP powder in a fine fiber form described above is used, and thus the LCP powder can be dispersed in a highly viscous dispersion medium.

Examples of the dispersion medium used in the dispersion step include butanediol, water, ethanol, terpineol, and a mixture of water and ethanol. For example, in a case where butanediol is used as the dispersion medium, a paste-like LCP powder is obtained. In a case where a mixture of water and ethanol is used as the dispersion medium, a slurry-like LCP powder is obtained.

In a case where a porous body including additives is produced, the LCP powder and the additives are mixed in this step to obtain a paste-like or slurry-like mixture of the LCP powder and the additives (hereinafter, the mixture of an LCP powder and additives may be simply referred to as “mixture”). A mixing ratio of the additive is preferably 50 vol % or less with respect to the mixture.

The dispersion step S11 according to the present embodiment includes a coarse pulverizing step S11a, a fine pulverizing step S11b, a coarse particle removing step S11c, and a fiberization step S11d. In dispersion step S11 according to the present embodiment, the LCP powder is dispersed in the dispersion medium in the process of producing the LCP powder from the LCP raw material.

### Coarse Pulverizing Step S11a

In the coarse pulverizing step, the LCP raw material is coarsely pulverized. For example, the LCP raw material is coarsely pulverized with a cutter mill. A size of the particles of the coarsely pulverized LCP is not particularly limited as long as the particles can be used as a raw material in the fine pulverizing step described later. A maximum particle size of the coarsely pulverized LCP is, for example, 3 mm or less.

The coarse pulverizing step is not necessarily performed. For example, if the LCP raw material can be used as a raw material in the fine pulverizing step, the LCP raw material may be directly used as a raw material in the fine pulverizing step.

### Fine Pulverizing Step S11b

In the fine pulverizing step, the LCP raw material (after the coarse pulverizing step) is pulverized in a state of being dispersed in liquid nitrogen to obtain a granular finely pulverized liquid crystal polymer (finely pulverized LCP). In the fine pulverizing step, it is preferable that the LCP raw material that is dispersed in the liquid nitrogen is pulverized using a medium. The medium is, for example, a bead. In the fine pulverizing step of the present embodiment, it is preferable to use a bead mill having relatively few technical problems from a viewpoint of handling liquid nitrogen. Examples of the apparatus that can be used in the fine pulverizing step include “LNM-08” that is a liquid nitrogen bead mill manufactured by AIMEX Corporation.

The granular finely pulverized LCP obtained by the fine pulverizing step preferably has a D50 of 50 μm or less as measured by a particle size distribution measuring apparatus by a laser diffraction scattering method. This makes it possible to suppress clogging of the granular finely pulverized LCP with the nozzle in the following fiberization step.

### Coarse Particle Removing Step S11c

Then, in the coarse particle removing step S11c, coarse particles are removed from the granular finely pulverized LCP obtained in the fine pulverizing step. For example, the granular finely pulverized LCP is sieved with a mesh to obtain the granular finely pulverized LCP under the sieve, and the coarse particles included in the granular finely pulverized LCP can be removed by removing the granular LCP on the sieve. A type of mesh may be appropriately selected, and examples of the mesh include a mesh having an opening of 53 μm. The coarse particle removing step S11c is not necessarily performed.

In the present embodiment, in the coarse particle removing step S11c, the granular finely pulverized LCP is dispersed in the dispersion medium before being sieved with a mesh. The dispersion liquid thus obtained is sieved with a mesh. Therefore, the obtained finely pulverized LCP also becomes the slurry-like finely pulverized LCP dispersed in the dispersion medium.

### Fiberization Step S11d

Then, in the fiberization step, the granular LCP is crushed by a wet high-pressure crushing apparatus to obtain LCP powder. The finely pulverized LCP in a state of being dispersed in the dispersion medium, that is, the paste-like or slurry-like finely pulverized LCP is passed through the nozzle in a state of being pressurized at high pressure. By passing through the nozzle at a high pressure, a shearing force or collision energy due to a high-speed flow in the nozzle acts on the LCP, and the granular finely pulverized LCP is crushed, whereby the fiberization of the LCP proceeds and LCP powder composed of fine LCP fibers can be obtained. A nozzle diameter of the nozzle is preferably as small as possible within a range in which clogging of the finely pulverized LCP does not occur in the nozzle from a viewpoint of applying high shear force or high collision energy. The granular finely pulverized LCP has a relatively small particle size, and thus the nozzle diameter in the wet high-pressure crushing apparatus used in the fiberization step can be reduced. The nozzle diameter is, for example, 0.2 mm or less.

As described above, a plurality of fine cracks are formed in the granular finely pulverized LCP. Therefore, the dispersion medium enters into the finely pulverized LCP through fine cracks by pressurization in a wet high-pressure crushing apparatus. Then, when the paste-like or slurry-like finely pulverized LCP passes through the nozzle and is positioned under normal pressure, the dispersion medium that has entered the finely pulverized LCP expands in a short time. When the dispersion medium that has entered the finely pulverized LCP expands, destruction progresses from inside of the finely pulverized LCP. Therefore, the fiberization proceeds to the inside of the finely pulverized LCP, and the molecules of the LCP are separated into domain units arranged in one direction. As described above, in the fiberization step according to the present embodiment, defiberizing the granular finely pulverized LCP obtained in the fine pulverizing step in the present embodiment makes it possible to obtain the LCP powder that has a low content of massive particles and is composed of fine LCP fibers as compared with the LCP powder obtained by crushing the granular LCP obtained by a conventional freeze pulverizing method. In the present embodiment, at this time point, a paste-like or slurry-like LCP powder is obtained.

In the fiberization step in the present embodiment, the finely pulverized LCP may be crushed by the wet high-pressure crushing apparatus a plurality of times to obtain the LCP powder, but from a viewpoint of production efficiency, the number of times of crushing by the wet high-pressure crushing apparatus is preferably small, and is, for example, 5 times or less.

In addition, when finely pulverized LCP is not dispersed in the dispersion medium in the coarse particle removing step S11c, slurry-like fine pulverized LCP obtained by dispersing fine pulverized LCP in the dispersion medium for the fiberization step may be used. Examples of the dispersion medium for the fiberization step include water, ethanol, methanol, isopropyl alcohol, toluene, benzene, xylene, phenol, acetone, methyl ethyl ketone, diethyl ether, dimethyl ether, hexane, and mixtures thereof.

### Molding Step S12

Then, in molding step S12, the paste-like or slurry-like LCP powder or mixture is dried to mold a sheet-shaped molded body of liquid crystal polymer fibers (LCP fiber molded body), a so-called LCP fiber mat. In an embodiment of the present disclosure, the molding step is, for example, a papermaking method. In the papermaking method, the dispersion medium used in the dispersion step can be easily recovered and reused, and porous bodies can be produced at low cost.

In the molding step S12 using the papermaking method, specifically, first, a slurry-like LCP powder or mixture is subjected to papermaking on a mesh, a nonwoven fabric-like microporous sheet, or a woven fabric. Then, the slurry-like LCP powder or mixture disposed on the mesh is heated and dried to obtain an LCP fiber molded body (porous resin layer).

In molding step S12 in the present embodiment, instead of the papermaking method, a paste-like LCP powder or mixture may be molded by an application step and a drying step to obtain an LCP fiber molded body.

In the application step, a paste-like LCP powder or mixture is applied to a substrate material. Herein, “substrate material” refers to the material or support material for applying the paste-like LCP powder or mixture, and examples thereof include metal foils such as a copper foil, a polyimide film, a PTFE film, or composite sheets composed of reinforcing materials such as carbon fibers and glass fibers and heat resistant resins.

Then, in the dry step, the paste-like LCP powder or mixture applied to the substrate material is heated and dried to vaporize the dispersion medium. The heating and drying forms the LCP fiber molded body on the substrate material.

In addition, in the dry step, the dispersion medium is gradually removed from the paste-like LCP powder or mixture, and thus the total thickness of the paste-like LCP powder or mixture gradually decreases during drying. Therefore, the thickness of the LCP fiber molded body is thinner compared to the total thickness of the paste-like LCP powder or mixture formed on the product.

Further, as the total thickness of the paste-like LCP powder or mixture gradually decreases during drying, the longitudinal direction of the fibrous particles in the LCP powder changes. Specifically, among the fibrous particles, the fibrous particles having the longitudinal direction in the entire thickness direction of the paste-like LCP powder or mixture are inclined such that the longitudinal direction is directed toward the in-plane direction of the main surface of the substrate material. Therefore, there is anisotropy in the longitudinal direction of the fibrous particles in the formed LCP fiber molded body.

In the mold step including the application step and the dry step, the dispersion medium may be vaporized by further applying the paste-like LCP powder or mixture onto the LCP fiber molded body formed on the substrate material by the dry step, and then drying the paste-like LCP powder or mixture. As described above, the mold step may include the application step and the dry step repeatedly in this order. As a result, an LCP fiber molded body having a desired basis weight can be obtained. In a case where the application step and the dry step are repeatedly performed, a mixture in which the mixing ratio of the LCP powder to the additives is changed for each application step may be used. As a result, an LCP fiber molded body (porous resin layer) having desired properties can be obtained.

### Plasma Treatment Step S2

Then, in a plasma treatment step S2, both surfaces of the LCP fiber molded body are irradiated with plasma. Only the surface on one side of the LCP fiber molded body may be subjected to plasma treatment. The LCP fiber molded body is not necessarily subjected to plasma treatment.

### First Press Step S3

Then, in a first press step S3, the first adhesive layer is bonded to the LCP fiber molded body (porous resin layer), and pressing for bonding the first metal layer to the first adhesive layer is performed. First, a sheet, a film, or a molded body for the first adhesive layer is laminated on a first metal foil (first metal layer), and the LCP fiber molded body is further laminated thereon to obtain a first laminate. This first laminate is pressed under vacuum. Thus, a laminated film having a metal layer only on one surface is obtained.

The temperature during the pressing in first press step S3 is preferably high from the viewpoint of enhancing the adhesion between the first adhesive layer and the LCP fiber molded body and the adhesion between the first adhesive layer and the first metal layer. On the other hand, in order to suppress excessive melting of the sheet, the film, or the molded body for the first adhesive layer, the temperature during pressing in the first press step S3 is preferably lower than the melting point of the resin included in the sheet, the film, or the molded body for the first adhesive layer. A value obtained by subtracting the temperature during pressing in the first press step S3 from the melting point of the resin included in the first adhesive layer is, for example, 15° C. to 85° C. The press pressure in the first press step S3 is, for example, 0.1 MPa to 8 MPa. The press time in the first press step S3 is, for example, 5 minutes to 20 minutes.

In the present embodiment, in the first press step S3, the sheet, the film, or the molded body for the second adhesive layer is also bonded to the LCP fiber molded body (porous resin layer). In the first press step S3, the sheet, the film, or the molded body for the second adhesive layer is laminated on the LCP fiber molded body previously before performing pressing. Then, a laminated film including the second adhesive layer is obtained by the above vacuum pressing. The laminated film having the metal layer only on one surface obtained in the first press step S3 may not include the second adhesive layer.

### Second Press Step S4

Then, in a second press step S4, the second metal layer is bonded to the second adhesive layer. First, in the laminated film obtained in the first press step S3, the second metal layer is laminated on the side opposite to the first metal layer side (on the first adhesive layer in the present embodiment) to obtain a second laminate. This laminate is pressed under vacuum to obtain a laminate film having metal on both surfaces.

The temperature during pressing in the second press step S4 is preferably high from the viewpoint of enhancing adhesion between the second adhesive layer and the second metal layer. On the other hand, in order to suppress excessive melting of the sheet, the film, or the mat for the second adhesive layer, the temperature during pressing in the second press step S4 is preferably lower than the melting point of the resin included in the sheet, the film, or the mat for the second adhesive layer. A value obtained by subtracting the temperature during pressing in the second press step S4 from the melting point of the resin included in the second adhesive layer is, for example, 15° C. to 50° C. The press pressure in the second press step S4 is, for example, 0.1 MPa to 8 MPa. The press time in the second press step S4 is, for example, 5 minutes to 20 minutes.

In the present embodiment, the sheet, the film, or the mat for the second adhesive layer is bonded to the LCP fiber molded body (porous resin layer) in the first press step S3, but the sheet, the film, or the mat for the second adhesive layer may be bonded to the LCP fiber molded body (porous resin layer) in the second press step S4. In this case, in the second press step S4, before performing pressing, the second adhesive layer may be laminated previously on the side opposite to the first adhesive layer side of the LCP fiber molded body, and the second metal layer may be further laminated thereon to obtain the second laminate. This laminate may be pressed under vacuum to obtain a laminated film having metal layers on both surfaces.

### EXAMPLES

Hereinafter, the present disclosure will be described in more detail with reference to the examples, but the present disclosure is not limited thereto.

### Example 1

In Example 1, an LCP fiber molded body was prepared as a porous resin layer as follows. First, as an LCP raw material, a cylindrical pellet of uniaxially oriented LCP having a pellet diameter of 3 to 4 mm, a melting point of 320° C.) was prepared. The material of LCP is a copolymer of parahydroxybenzoic acid and 4,6-hydroxynaphthoic acid. This LCP raw material was coarsely pulverized with a cutter mill (“MF10” manufactured by IKA Group). The coarsely pulverized LCP was passed through a mesh having a diameter of 3 mm provided at a discharge port of the cutter mill to obtain a coarsely pulverized LCP.

Then, the coarsely pulverized LCP was finely pulverized with a liquid nitrogen bead mill (LNM-08 manufactured by AIMEX Corporation, vessel capacity: 0.8 L). Specifically, 500 mL of media and 30 g of coarsely pulverized LCP were put into a vessel, and pulverization treatment was performed at a rotation speed of 2000 rpm for 120 minutes. As the medium, beads made of zirconia (ZrO₂) having a diameter of 5 mm were used. In the liquid nitrogen bead mill, wet pulverizing treatment is performed in a state in which the coarsely pulverized LCP is dispersed in the liquid nitrogen. As described above, pulverizing the coarsely pulverized LCP with the liquid nitrogen bead mill provided granular finely pulverized LCP.

Then, finely pulverized LCP was dispersed in a 20 mass % ethanol aqueous solution as a dispersion medium to obtain a dispersion liquid in which finely pulverized LCP was dispersed. This dispersion liquid was sieved with a mesh having an opening of 106 μm. As a result, the finely pulverized LCP from which the coarse particles were removed by passing through the mesh was recovered in a state of being dispersed in the dispersion liquid.

Then, the finely pulverized LCP from which the coarse particles had been removed was repeatedly pulverized 5 times under the conditions of a nozzle diameter of 0.2 mm and a pressure of 200 MPa using a wet high-pressure crushing apparatus in a state of being dispersed in a dispersion liquid to be made into fiber. As a wet high-pressure crushing apparatus, a high-pressure disperser (“STAR BURST LABO” manufactured by Sugino Machine Limited) was used. Fiberization of finely pulverized LCP provided a slurry-like LCP powder including LCP fibers in which the LCP powder was dispersed in an ethanol aqueous solution.

Then, a slurry-like LCP powder was subjected to papermaking using a square sheet machine (manufactured by KUMAGAI RIKI KOGYO Co., Ltd.) on a polyester microfiber nonwoven fabric (basis weight: 14 g/m²) placed on an 80 mesh wire mesh to obtain a dispersion medium-containing LCP fiber molded body. Then, the dispersion medium-containing LCP fiber molded body was dried with a hot air dryer, and peeled off from the polyester microfiber nonwoven fabric to obtain an LCP fiber molded body (porous resin layer). In the papermaking of the slurry-like LCP powder, the amount of the LCP powder was adjusted such that the basis weight of the LCP fiber molded body was 18 g/m².

Then, both surfaces of the obtained LCP fiber molded body were subjected to plasma treatment by a plasma irradiation apparatus (“PC-1000” manufactured by Samco Inc.). The plasma treatment was performed for 5 minutes under the conditions of 10 Pa or less, an O₂ gas flow rate of 50 sccm, and 800 W. As a result, a plasma-treated LCP fiber molded body was obtained.

Then, a first electrolytic copper foil (first metal layer) having a roughened surface and a thickness of 12 μm, a first epoxy-based adhesive sheet (first adhesive layer) having a thickness of 15 μm, a plasma-treated LCP fiber molded body, a second epoxy-based adhesive sheet (second adhesive layer) having a thickness of 15 μm, and a release film composed of PET (polyethylene terephthalate) were laminated in this order to obtain a first laminate. In this case, the first epoxy-based adhesive sheet was placed on the first electrolytic copper foil so as to be in contact with the roughened surface of the first electrolytic copper foil. Then, the first laminate was pressed under vacuum with a high temperature vacuum press machine (“KVHC” manufactured by KITAGAWA SEIKI Co., LTD.) at a temperature of 100° C. and a press pressure of 6 MPa for 5 minutes. The release film was peeled off from the pressed first laminate to obtain a single-sided copper-clad film (laminated film) in which the first adhesive layer and the second adhesive layer were laminated on each of both surfaces of the LCP fiber molded body.

Then, a second electrolytic copper foil (second metal layer) having a roughened surface and a thickness of 12 μm was superposed on the second adhesive layer of the obtained single-sided copper-clad film to obtain a second laminate. In this case, the second electrolytic copper foil was superposed on the second epoxy-based adhesive sheet such that the roughened surface of the second electrolytic copper foil was in contact with the second epoxy-based adhesive sheet. Then, this second laminate was pressed under vacuum with a high temperature vacuum press machine (“KVHC” manufactured by KITAGAWA SEIKI Co., LTD.) at a temperature of 170° C. and a press pressure of 6 MPa for 5 minutes to obtain a double-sided copper-clad laminate (laminated film).

### Example 2

A double-sided copper-clad laminate (laminated film) was obtained by the same production method as in Example 1 except that the first laminate was pressed at a press pressure of 0.1 MPa and the second laminate was pressed at a press pressure of 0.1 MPa.

### Example 3

In Example 3, a double-sided copper-clad laminate was obtained by a production method in which a part of the laminated film production method according to Example 1 was changed.

Specifically, as the LCP raw material in the LCP fiber molded body as the porous resin layer, one made of a copolymer of parahydroxybenzoic acid, terephthalic acid, and dihydroxybiphenyl (melting point: 350° C.) was used. A plasma-treated first LCP film was used instead of the first epoxy-based adhesive sheet. A plasma-treated second LCP film was used instead of the second epoxy-based adhesive sheet. As the first LCP film and the second LCP film, one having a melting point of 320° C. and made of a copolymer of parahydroxybenzoic acid and 4,6-hydroxynaphthoic acid was used. Plasma treatment of the first LCP film and the second LCP film was performed for 5 minutes under the conditions of 10 Pa or less, a flow rate of O₂ gas of 50 sccm, and 800 W. As the release film included in the first laminate, a polyimide release film was used. The first laminate was vacuum-pressed at a temperature of 270° C. and a press pressure of 8 MPa for 20 minutes. The second laminate was vacuum-pressed at a temperature of 270° C. and a press pressure of 8 MPa for 20 minutes. Except for these points, a double-sided copper-clad laminate was obtained in the same manner as in Example 1.

### Example 4

In Example 4, a double-sided copper-clad laminate was obtained by a production method in which a part of the laminated film production method according to Example 1 was changed.

Specifically, as the LCP raw material in the LCP fiber molded body as the porous resin layer, one made of a copolymer of parahydroxybenzoic acid, terephthalic acid, and dihydroxybiphenyl (melting point: 350° C.) was used. In addition, instead of the first epoxy-based adhesive sheet, a plasma-treated LCP fiber molded body for a first adhesive layer was used. Instead of the second epoxy-based adhesive sheet, a plasma-treated LCP fiber molded body for a second adhesive layer was used. As the LCP fiber molded body for the first adhesive layer and the second epoxy-based adhesive sheet, the same one as the LCP fiber molded body (melting point: 320° C.) prepared in Example 1 was used. The plasma treatment of the LCP fiber molded body for the first adhesive layer and the LCP fiber molded body for the second adhesive layer was performed for 5 minutes under the conditions of 10 Pa or less, and the O₂ gas flow rate of 50 sccm and 800 W. As the release film included in the first laminate, a polyimide release film was used. The first laminate was vacuum-pressed at a temperature of 305° C. and a press pressure of 6 MPa for 5 minutes. The second laminate was vacuum-pressed at a temperature of 305° C. and a press pressure of 6 MPa for 5 minutes. Except for these points, a double-sided copper-clad laminate was obtained in the same manner as in Example 1.

### COMPARATIVE EXAMPLE

A double-sided copper-clad laminate was obtained in the same manner as in Example 1 except that a porous polyimide film was used as the porous resin layer instead of the LCP fiber molded body.

### REFERENCE EXAMPLE

A double-sided copper-clad laminate was obtained in the same manner as in Example 3 except that the LCP fiber molded body, the first LCP film, and the second LCP film were not subjected to plasma treatment.

### Measurement of Dielectric Loss Tangent

The first electrolytic copper foil and the second electrolytic copper foil were removed from each double-sided copper-clad laminate according to Examples 1 to 4 and Comparative Example 1 by etching to prepare a test piece of 30 mm×30 mm. The dielectric loss tangent of the test piece was measured by a cavity resonator method using a dielectric constant measurement apparatus in accordance with JIS R1641. The measurement was performed by applying a high-frequency signal of 12 GHz at an ambient temperature of 25° C.

### Evaluation of Adhesion

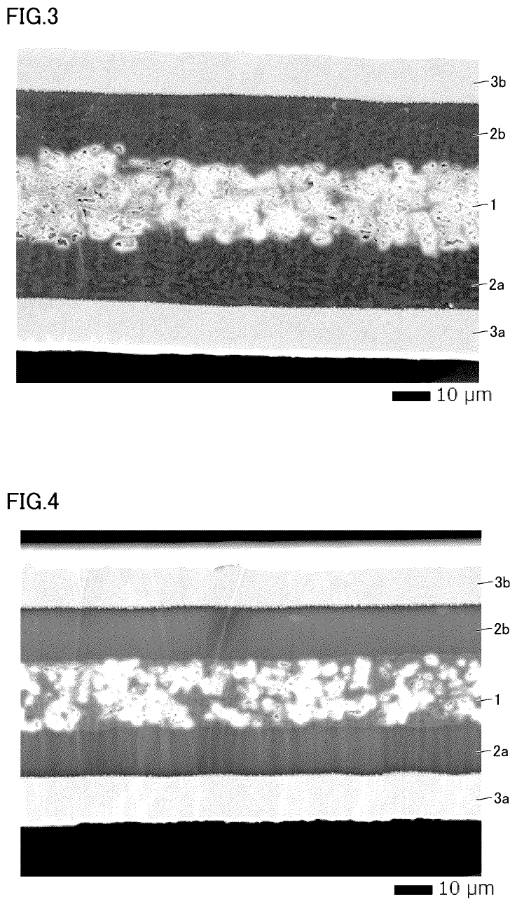

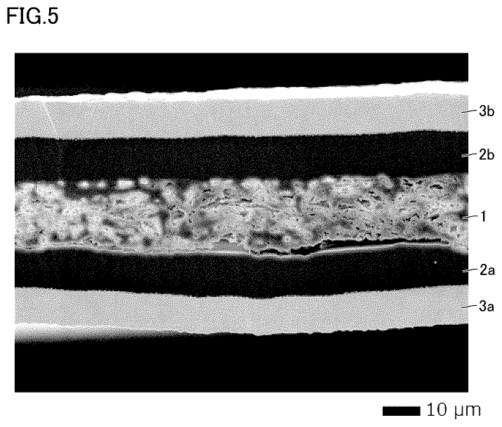

Each of the double-sided copper-clad laminates of Examples 1 to 4, Comparative Example 1, and Reference Example was subjected to sectional milling at an accelerating voltage of 1.5 kV to 4 kV for 30 minutes using an ion milling apparatus (“IM 4000” manufactured by Hitachi High-Tech Corporation) to expose the section. The section was observed with a SEM (scanning electron microscope). For example, FIG. 3 is a sectional observation photograph by SEM of the double-sided copper-clad laminate according to Example 1. FIG. 4 is a sectional observation photograph by SEM of the double-sided copper-clad laminate according to Example 4. FIG. 5 is a sectional observation photograph by SEM of the double-sided copper-clad laminate according to Reference Example. In FIGS. 3 to 5, layers corresponding to the respective layers according to an embodiment of the present disclosure are denoted by reference numerals. By visually observing the section, the adhesion between the porous resin layer, and the first adhesive layer and the second adhesive layer was evaluated according to the following criteria.
A: The number of voids located at the boundary between the porous resin layer, and the first adhesive layer and the second adhesive layer was relatively significantly small.
B: The number of voids located at the boundary between the porous resin layer, and the first adhesive layer and the second adhesive layer was relatively small.
C: A relatively large void was observed at the boundary between the porous resin layer, and the first adhesive layer and the second adhesive layer.

### Calculation of Porosity of Porous Resin Layer

For each of the double-sided copper-clad laminates according to Examples 1 to 4 and Comparative Example 1, the thickness of the porous resin layer was measured during observation of the section. The porosity of the porous resin layer was calculated based on the thickness, the weight of the porous resin layer in the double-sided copper-clad laminate, and the density of the resin raw material of the porous resin layer.

### Measurement of Average Pore Size of Porous Resin Layer

For each double-sided copper-clad laminate according to Examples 1 to 4 and Comparative Example 1, the first metal layer and the second metal layer were peeled off, and the porous resin layer was torn to prepare a test piece. For this test piece, the pore size distribution was measured using a mercury intrusion porosimeter (“AutoPore V9605” manufactured by Micromeritics Instrument Corporation). The average pore size of the test piece was calculated from the pore size distribution.

Table 1 shows the measured values of the dielectric loss tangent, the evaluation results of the adhesion, the calculated values of the porosity, and the measured values of the average pore size of each of the double-sided copper-clad laminates according to Examples 1 to 4 and Comparative Example 1. The result of the adhesion evaluation on the double-sided copper-clad laminate according to Reference Example was “C”.

TABLE 1

| | | | | | | Comparative |
|---|---|---|---|---|---|---|
| | | Example 1 | Example 2 | Example 3 | Example 4 | Example 1 |
| Porous | Type | LCP fiber | LCP fiber | LCP fiber | LCP fiber | Polyimide |
| resin | | molded | molded | molded | molded | porous |
| layer | | body | body | body | body | body |
| | LCP raw | 320 | 320 | 350 | 350 | — |
| | material | | | | | |
| | melting point | | | | | |
| | [° C.] | | | | | |
| First | Type | Epoxy-based | Epoxy-based | LCP film | LCP fiber | Epoxy-based |
| adhesive | | adhesive | adhesive | | molded | adhesive |
| layer | | sheet | sheet | | body | sheet |
| | LCP raw | — | — | 320 | 320 | — |
| | material | | | | | |
| | melting point | | | | | |
| | [° C.] | | | | | |
| Second | Type | Epoxy-based | Epoxy-based | LCP film | LCP fiber | Epoxy-based |
| adhesive | | adhesive | adhesive | | molded | adhesive |
| layer | | sheet | sheet | | body | sheet |
| | LCP raw | — | — | 320 | 320 | — |
| | material | | | | | |
| | melting point | | | | | |
| | [° C.] | | | | | |
| First | Temperature | 100 | 100 | 270 | 305 | 100 |
| press | [° C.] | | | | | |
| step | Pressure [MPa] | 6 | 0.1 | 8 | 6 | 6 |
| | Time [min] | 5 | 5 | 20 | 5 | 5 |
| Second | Temperature | 170 | 170 | 270 | 305 | 170 |
| press | [° C.] | | | | | |
| step | Pressure [MPa] | 6 | 0.1 | 8 | 6 | 6 |
| | Time [min] | 5 | 5 | 20 | 5 | 5 |

| | | | | | |
|---|---|---|---|---|---|
| Dielectric loss tangent | 0.003 | 0.002 | 0.001 | 0.0008 | 0.01 |
| Adhesion | B | B | B | A | B |
| Porosity | 31% | 50% | 25% | 27% | 50% |
| Average pore size [μm] | 0.11 | 0.91 | 0.35 | 0.25 | 0.40 |

As shown in Table 1, the dielectric loss tangent of the laminated films according to Examples 1 to 4 in which the porous resin layer was a molded body of liquid crystal polymer fibers was 0.003 or less. In contrast, the dielectric loss tangent of the laminated film according to Comparative Example 1 in which the porous resin layer was not a molded body of liquid crystal polymer fibers was 0.01, which was larger than that in Examples 1 to 4. Therefore, the porous resin layer was a molded body of liquid crystal polymer fibers, thereby allowing the dielectric loss of the laminated film to be reduced.

Further, in the laminated film according to Examples 1 to 4, the porous resin layer has a porosity of 25% to 50%. The porosity was 25% to 50%, thereby allowing the dielectric constant of the porous resin layer to be made relatively low, and the porous resin layer was a molded body of liquid crystal polymer fibers, thereby allowing the dielectric loss tangent of the laminated film to be reduced.

Further, the porous resin layer of the laminated film according to Examples 1 to 4 had an average pore size of 1 μm or less as measured by a mercury intrusion method. In such a porous resin layer having an average pore size of 1 μm or less, the porous resin layer was a molded body of liquid crystal polymer fibers, thereby allowing the dielectric loss tangent of the laminated film to be reduced.

Further, the first adhesive layer and the second adhesive layer of the laminated films according to Examples 3 and 4 each include a liquid crystal polymer. The laminated films according to Examples 3 and 4 had a dielectric loss tangent of 0.001 or less. On the other hand, the first adhesive layer and the second adhesive layer of the laminated films according to Examples 1 and 2 do not include a liquid crystal polymer. The laminated films according to Examples 1 and 2 showed 0.003 and 0.002 larger than Examples 3 and 4, respectively. Therefore, at least one or both of the first adhesive layer and the second adhesive layer included a liquid crystal polymer, thereby allowing the dielectric loss tangent of the laminated film to be further reduced.

Further, in the laminated films according to Examples 3 and 4, the melting point of the liquid crystal polymer included in the porous resin layer was 350° C., and the melting points of the liquid crystal polymer included in the first adhesive layer and the second adhesive layer were 320° C. That is, in the laminated films according to Examples 3 and 4, the melting point of the liquid crystal polymer included in the porous resin layer is higher than the melting point of the liquid crystal polymer included in at least one or both of the first adhesive layer and the second adhesive layer. As a result, it became easy to heat the first adhesive layer and the second adhesive layer to bond the first adhesive layer and the second adhesive layer to another layer while maintaining the function as a porous resin layer in the molded body of liquid crystal polymer fibers. In addition, in the laminated films according to Examples 3 and 4, the melting point of the liquid crystal polymer included in the porous resin layer is higher by 20° C. or more than the melting point of the liquid crystal polymer included in at least one or both of the first adhesive layer and the second adhesive layer. As a result, it became easier to heat the first adhesive layer and the second adhesive layer to bond the first adhesive layer and the second adhesive layer to another layer while maintaining the function as a porous resin layer in the molded body of liquid crystal polymer fibers.

Further, in the laminated film according to Example 4, both the first adhesive layer and the second adhesive layer are molded bodies of liquid crystal polymer fibers, and in the laminated films according to Examples 1 to 3, both the first adhesive layer and the second adhesive layer are not molded bodies of liquid crystal polymer fibers. The laminated film according to Example 4 had better adhesion between the porous resin layer, and the first adhesive layer and the second adhesive layer than the laminated films according to Examples 1 to 3. Therefore, the porous resin layer, and at least one or both of the first adhesive layer and the second adhesive layer were molded bodies of liquid crystal polymer fibers, thereby allowing the fibrous liquid crystal polymers to be entangled with each other, and adhesion between the porous resin layer, and the first adhesive layer and the second adhesive layer to be enhanced.

Further, in the laminated film according to Example 4, in the first press step, the first laminate including the porous resin layer and the molded body of liquid crystal polymer fibers as the first adhesive layer is pressed, thereby causing the porous resin layer and the first adhesive layer to be bonded to each other. In addition, in the first press step, the first laminate including the porous resin layer and the molded body of the liquid crystal polymer fiber as the second adhesive layer is pressed, thereby causing the porous resin layer and the second adhesive layer to be bonded to each other. Such pressing causes further entanglement of the fibrous LCP polymer in the molded body of the liquid crystal polymer fiber as the porous resin layer with the fibrous LCP in the molded body of the liquid crystal polymer fiber as the first adhesive layer or the second adhesive layer. As a result, adhesion between the porous resin layer and the first adhesive layer could be enhanced, and adhesion between the porous resin layer and the second adhesive layer could be further enhanced.

In the description of the above embodiments, the disclosed configurations may be combined with each other.

The embodiments and examples disclosed herein are all to be considered by way of examples in all respects, but not limiting. The scope of the present disclosure is specified by the claims, but not the above description, and intended to encompass all modifications within the spirit and scope equivalent to the claims.

### DESCRIPTION OF REFERENCE SYMBOLS

1: Porous resin layer
2a: First adhesive layer
2b: Second adhesive layer
3a: First metal layer
3b: Second metal layer
10: Laminated film

1. A laminated film, comprising:
a porous resin layer comprising a first molded body of first liquid crystal polymer fibers;
a first adhesive layer on the porous resin layer;
a metal layer on the first adhesive layer on a side thereof opposite to the porous resin layer as viewed from the first adhesive layer; and
a second adhesive layer on the porous resin layer on a side thereof opposite to the first adhesive layer as viewed from the porous resin layer,
wherein the porous resin layer has a porosity of 25% to 50%,
wherein at least one of the first adhesive layer and the second adhesive layer includes second liquid crystal polymer fibers, and
wherein a melting point of the first liquid crystal polymer fibers in the porous resin layer is higher than a melting point of the second liquid crystal polymer fibers in the at least one of the first adhesive layer and the second adhesive layer.

2. The laminated film according to claim 1, wherein the porous resin layer has an average pore size of 1 μm or less as measured by a mercury intrusion method.

3. The laminated film according to claim 1, wherein the melting point of the first liquid crystal polymer fibers in the porous resin layer is higher by 20° C. or more than the melting point of the second liquid crystal polymer fibers in the at least one of the first adhesive layer and the second adhesive layer.

4. The laminated film according to claim 1, wherein the at least one of the first adhesive layer and the second adhesive layer comprises a second molded body of the second liquid crystal polymer fibers.

5. The laminated film according to claim 1, wherein an average diameter of the first liquid crystal polymer fibers is 2 μm or less.

6. The laminated film according to claim 1, wherein an average aspect ratio of the first liquid crystal polymer fibers is 10 to 500.

7. A laminated film, comprising:
a porous resin layer comprising a first molded body of first liquid crystal polymer fibers;
a first adhesive layer on the porous resin layer;
a metal layer on the first adhesive layer on a side thereof opposite to the porous resin layer as viewed from the first adhesive layer; and
a second adhesive layer on the porous resin layer on a side thereof opposite to the first adhesive layer as viewed from the porous resin layer,
wherein the porous resin layer has an average pore size of 1 μm or less as measured by a mercury intrusion method,
wherein at least one of the first adhesive layer and the second adhesive layer includes second liquid crystal polymer fibers, and
wherein a melting point of the first liquid crystal polymer fibers in the porous resin layer is higher than a melting point of the second liquid crystal polymer fibers in the at least one of the first adhesive layer and the second adhesive layer.

8. The laminated film according to claim 7, wherein the melting point of the first liquid crystal polymer fibers in the porous resin layer is higher by 20°C or more than the melting point of the second liquid crystal polymer fibers in the at least one of the first adhesive layer and the second adhesive layer.

9. The laminated film according to claim 7, wherein the at least one of the first adhesive layer and the second adhesive layer comprises a second molded body of the second liquid crystal polymer fibers.

10. The laminated film according to claim 7, wherein an average diameter of the first liquid crystal polymer fibers is 2 μm or less.

11. The laminated film according to claim 7, wherein an average aspect ratio of the first liquid crystal polymer fibers is 10 to 500.

12. A method for producing a laminated film, the method comprising:
providing a laminate that includes:
a porous resin layer comprising a first molded body of first liquid crystal polymer fibers;
a first adhesive layer on the porous resin layer;
a metal layer on the first adhesive layer on a side thereof opposite to the porous resin layer as viewed from the first adhesive layer; and
a second adhesive layer on the porous resin layer on a side thereof opposite to the first adhesive layer as viewed from the porous resin layer,
wherein the porous resin layer has a porosity of 25% to 50%,
wherein at least one of the first adhesive layer and the second adhesive layer includes second liquid crystal polymer fibers, and
wherein a melting point of the first liquid crystal polymer fibers in the porous resin layer is higher than a melting point of the second liquid crystal polymer fibers in the at least one of the first adhesive layer and the second adhesive layer; and
pressing the laminate so as to bond the porous resin layer and the first adhesive layer and/or the porous resin layer and the second adhesive layer to each other.

13. The method for producing a laminated film according to claim 12, wherein the porous resin layer has an average pore size of 1 μm or less as measured by a mercury intrusion method.

14. The method for producing a laminated film according to claim 12, wherein the melting point of the first liquid crystal polymer fibers in the porous resin layer is higher by 20° C. or more than the melting point of the second liquid crystal polymer fibers in the at least one of the first adhesive layer and the second adhesive layer.

15. The method for producing a laminated film according to claim 12, wherein an average diameter of the first liquid crystal polymer fibers is 2 μm or less.

16. The method for producing a laminated film according to claim 12, wherein an average aspect ratio of the first liquid crystal polymer fibers is 10 to 500.

17. The method for producing a laminated film according to claim 12, wherein at least one surface of the first molded body is irradiated with plasma before the pressing of the laminate.
